(19) United States
(12) Patent Application Publication
(10) Pub. No.: US 2026/0060129 A1
(43) Pub. Date: Feb. 26, 2026

(54) METHOD OF MANUFACTURING SEMICONDUCTOR PACKAGE AND APPARATUS FOR MANUFACTURING THE SAME

(71) Applicant: Samsung Electronics Co., Ltd., Suwon-si (KR)

(72) Inventor: Daehyun KIM, Suwon-si (KR)

(73) Assignee: Samsung Electronics Co., Ltd., Suwon-si (KR)

(21) Appl. No.: 19/057,155

(22) Filed: Feb. 19, 2025

(30) Foreign Application Priority Data
Aug. 22, 2024 (KR) 10-2024-0112537

(51) Int. Cl. H01L 21/56; H01L 21/67; H10D 89/00

(52) U.S. Cl. CPC H01L 21/561; H01L 21/566; H01L 21/67126; H10D 89/015

(57) ABSTRACT

A method of manufacturing a semiconductor package includes disposing a substrate strip having a plurality of semiconductor chips in a bottom mold, the bottom mold including sets of injection holes arranged on one side of the substrate strip, coupling the bottom mold and a top mold to contact each other, the top mold including cavities open toward corresponding ones of the sets of injection holes, individually injecting a first molding material and a second molding material into each of the cavities through injection holes included in a corresponding one of the sets of injection holes, respectively, forming a molding compound including the first molding material and the second molding material in the cavities, separating the top mold and the bottom mold from each other, curing the molding compound covering the semiconductor chips to form a mold structure, and cutting the mold structure.

### CROSS-REFERENCE TO RELATED APPLICATION(S)

This application claims the benefit under 35 USC 119(a) of Korean Patent Application No. 10-2024-0112537 filed on Aug. 22, 2024 in the Korean Intellectual Property Office, the entire disclosure of which is incorporated herein by reference for all purposes.

### BACKGROUND

The present inventive concepts relate to methods and apparatuses for manufacturing a semiconductor package.

The mold process of a semiconductor package injects a molding compound into a mold to form an encapsulant layer that seals the semiconductor chip. In the case of the molding compound, which is a mixture of a main agent and a curing agent, curing is performed at room temperature, and thus, it has a short shelf life, is difficult to store, and increases the manufacturing costs of the semiconductor package.

### SUMMARY

Some example embodiments provide methods and apparatuses for manufacturing a semiconductor package with improved productivity.

According to some example embodiments, a method of manufacturing a semiconductor package includes disposing a substrate strip having a plurality of semiconductor chips in a bottom mold, the bottom mold including sets of injection holes arranged on one side of the substrate strip, coupling the bottom mold and a top mold to contact each other, the top mold including a plurality of cavities, the plurality of cavities being open toward corresponding ones of the sets of injection holes, respectively, individually injecting a first molding material and a second molding material into each of the plurality of cavities through injection holes included in a corresponding one of the sets of injection holes, respectively, forming a molding compound including the first molding material and the second molding material in the plurality of cavities, separating the top mold and the bottom mold from each other such that the molding compound flows out of the plurality of cavities, during the molding compound covering the plurality of semiconductor chips and to form a mold structure, and cutting the mold structure.

According to some example embodiments, a method of manufacturing a semiconductor package includes disposing a substrate strip in a bottom mold, the bottom mold including a plurality of injection holes, coupling a top mold and the bottom mold to contact each other, the top mold including a plurality of cavities open toward the plurality of injection holes, each of the plurality of cavities vertically overlapping at least two injection holes adjacent to each other, among the plurality of injection holes, injecting a first molding material and a second molding material into the at least two injection holes, respectively, forming a molding compound including the first molding material and the second molding material in the plurality of cavities, separating the top mold and the bottom mold such that the molding compound flows onto the substrate strip, and forming a mold structure by curing the molding compound.

According to some example embodiments, an apparatus for manufacturing a semiconductor package includes a bottom mold including a pair of mounting surfaces and a plurality of injection holes, the plurality of injection holes being in a first horizontal direction and between the pair of mounting surfaces, and a top mold including a plurality of first cavities and second cavities, the plurality of first cavities being in the first horizontal direction and open toward the plurality of injection holes, and the second cavities corresponding to the pair of mounting surfaces, respectively, wherein each of the plurality of first cavities vertically overlap at least two injection holes adjacent to each other, among the plurality of injection holes, respectively.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a perspective view of an apparatus for manufacturing a semiconductor package according to an example embodiment;

FIGS. 2A to 2F are cross-sectional side views of an apparatus for manufacturing a semiconductor package according to some example modifications;

FIG. 3 is a flowchart illustrating a method of manufacturing a semiconductor package according to an example embodiment;

FIG. 4 is a drawing illustrating ‘S201’ and ‘S202’ of FIG. 3;

FIGS. 5A and 5B are drawings illustrating ‘S203’ and ‘S204’ of FIG. 3;

FIGS. 6A and 6B are drawings illustrating ‘S205’ and ‘S206’ of FIG. 3;

FIG. 7 is a drawing illustrating ‘S207’ of FIG. 3; and

FIGS. 8 and 9 are drawings illustrating a semiconductor package manufactured according to some example embodiments.

### DETAILED DESCRIPTION

Hereinafter, with reference to the accompanying drawings, some example embodiments of the present inventive concepts will be described as follows. Unless otherwise specified, in this specification, terms such as “upper,” “upper surface,” “lower,” “lower surface,” “side” and the like are based on the drawings, and actually, may vary depending on the direction in which the components are disposed.

Additionally, ordinal numbers such as “first,” “second,” “third,” etc. may be used as labels for specific elements, steps, directions, etc. to distinguish various elements, steps, directions, etc. from each other. Terms that are not described using “first,” “second,” etc. in the specification may still be referred to as “first” or “second” in the claims. Additionally, terms (for example, “first” in a particular claim) referenced by a particular ordinal number may be described elsewhere with a different ordinal number (for example, “second” in the specification or another claim).

As used herein, expressions such as “one of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

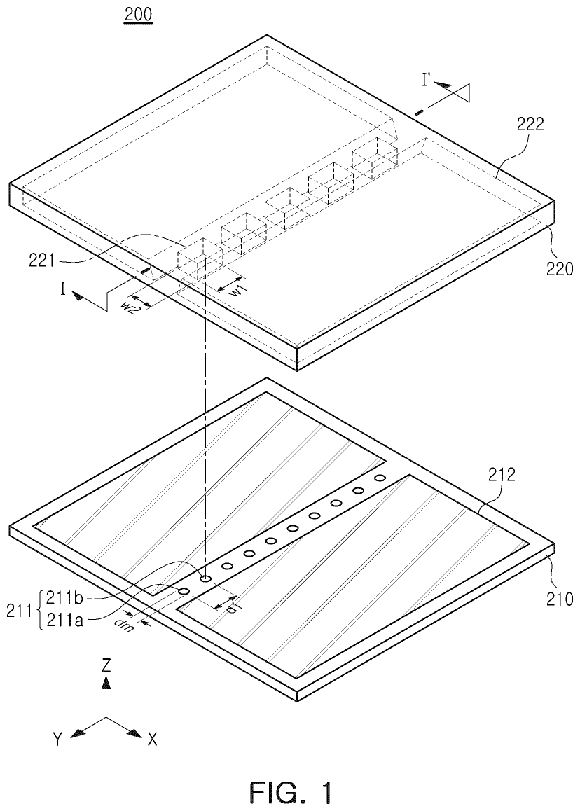

FIG. 1 is a perspective view of an apparatus 200 for manufacturing a semiconductor package according to an example embodiment.

Referring to FIG. 1, the apparatus 200 for manufacturing a semiconductor package according to an example embodiment may include a bottom mold 210 and a top mold 220. The bottom mold 210 and/or the top mold 220 may be configured to rise and fall in a vertical direction (Z-direction) to contact or separate from each other.

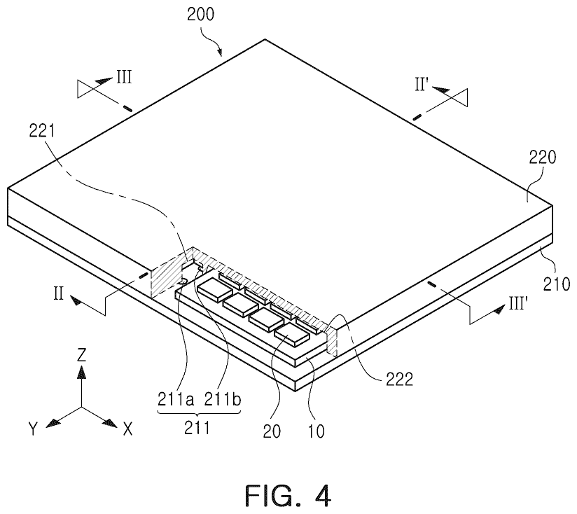

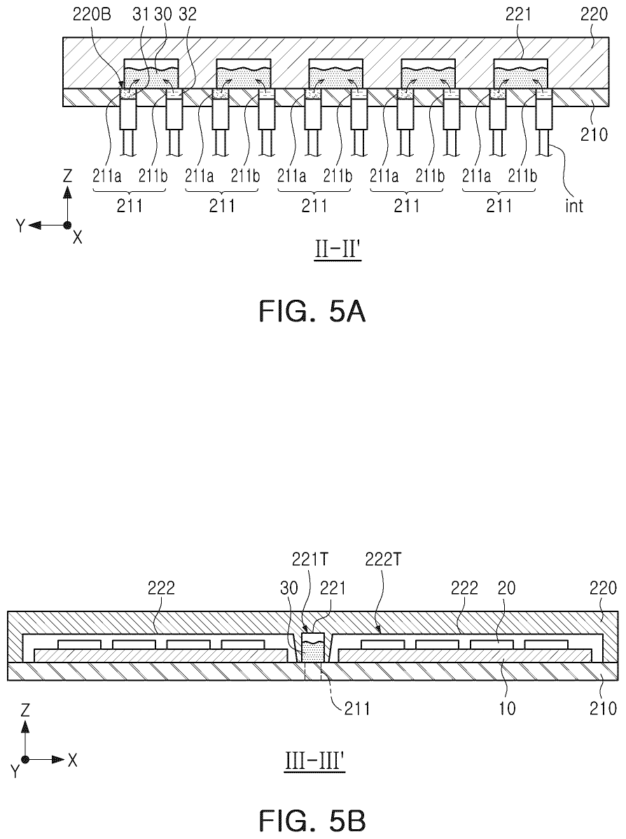

The bottom mold 210 may include a plurality of injection holes 211 and at least one mounting surface 212. For example, the bottom mold 210 may include a pair of mounting surfaces 212 and a plurality of injection holes 211. A pair of mounting surfaces 212 may be spaced apart in a second horizontal direction (X-direction), and the plurality of injection holes 211 may be arranged in a first horizontal direction (Y-direction) between the pair of mounting surfaces 212. The plurality of injection holes 211 may provide injection paths for molding materials (see FIGS. 5A and 5B). The plurality of injection holes 211 may be holes that penetrate the bottom mold 210 in a vertical direction (Z-direction). The plurality of injection holes 211 may be arranged along one side of the mounting surface 212. The mounting surface 212 may provide a mounting area for a substrate strip in a molding process of a semiconductor package (see FIG. 4). The mounting surface 212 may be a flat surface defined on one surface of the bottom mold 210, or may be a cavity having a flat bottom surface.

The top mold 220 is a mold facing the bottom mold 210 and may be configured to cover the mounting surface 212 of the bottom mold 210. The top mold 220 may be configured to provide a release film for separating the mold structure on one side or both sides. The top mold 220 may include a plurality of first cavities 221 and at least one or more second cavities 222. The plurality of first cavities 221 may be understood as a space open toward the corresponding plurality of injection holes 211. The at least one second cavity 222 may be understood as a space open toward the corresponding mounting surface 212. For example, the top mold 220 may include a plurality of first cavities 221 open toward a plurality of injection holes 211 and a pair of second cavities 222 respectively open toward a pair of mounting surfaces 212, respectively. The plurality of first cavities 221 may be arranged in a first horizontal direction (Y-direction) between a pair of second cavities 222 spaced apart in a second horizontal direction (X-direction).

According to an example embodiment, the plurality of first cavities 221 provide a space in which different types of molding materials (e.g., a main agent and a curing agent) are mixed to form a molding compound (see FIGS. 5A and 5B), thereby reducing the storage cost of the molding compound and the like and improving the productivity of the semiconductor package. Each of the plurality of first cavities 221 may vertically overlap two or more adjacent injection holes 211a and 211b among the plurality of injection holes 211. For example, the plurality of injection holes 211 may include a first injection hole 211a and a second injection hole 211b that are adjacent in a first horizontal direction (Y-direction), and the first injection hole 211a and the second injection hole 211b may vertically overlap a corresponding one first cavity 221 in the Z-direction. The first injection hole 211a and the second injection hole 211b may provide injection paths for the main agent and the curing agent, respectively.

The first width w1 of each of the plurality of first cavities 221 in the first horizontal direction (Y-direction) may be equal to or larger than the distance d1 between the center of the first injection hole 211a and the center of the second injection hole 211b. The second width w2 of each of the plurality of first cavities 221 in the second horizontal direction (X-direction) may be larger than the diameter (dm) of each of the plurality of injection holes 211. In this specification, two or more injection holes (e.g., the first injection hole 211a and the second injection hole 211b) connected to or associated with the same first cavity 221 in the package manufacturing process described later may be referred to as an ‘injection hole set 211’.

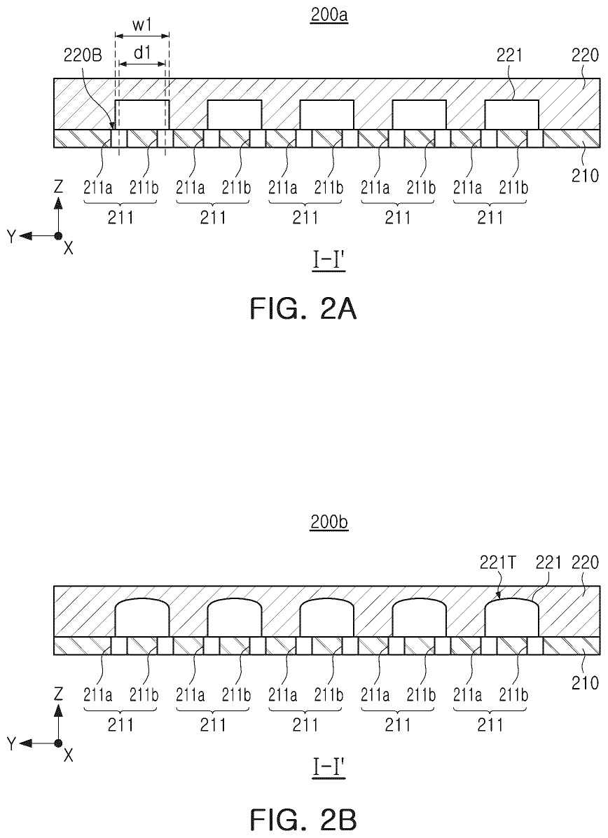

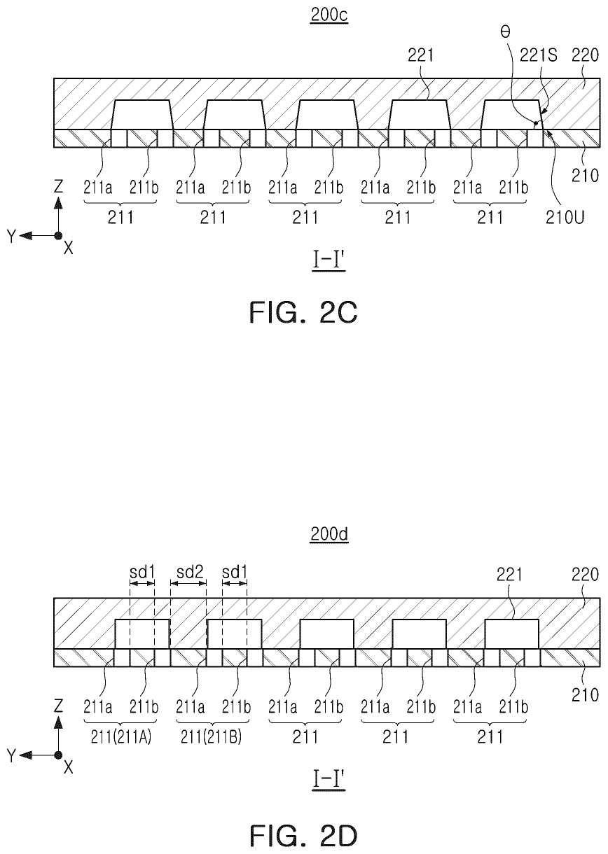

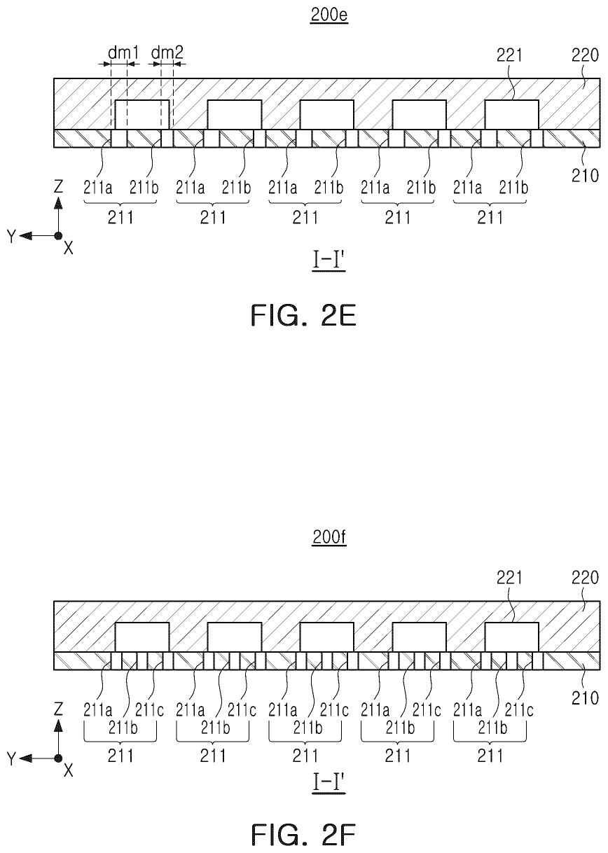

Hereinafter, with reference to FIGS. 2A to 2F, injection hole sets 211 and first cavities 221 according to some example modifications will be described.

FIGS. 2A to 2F are cross-sectional views of apparatuses 200a, 200b, 200c, 200d, 200e and 200f for manufacturing a semiconductor package according to some example modifications. FIGS. 2A to 2F respectively illustrate a cross-section taken along line I-I′ of FIG. 1.

Referring to FIG. 2A, an apparatus 200a for manufacturing a semiconductor package according to an example modification may include a bottom mold 210 including injection hole sets 211 arranged in a first horizontal direction (Y-direction), and a top mold 220 including a plurality of cavities 221 open toward the corresponding injection hole sets 211. Each of the plurality of cavities 221 may correspond to one injection hole set 211. For example, one injection hole set 211 may include a first injection hole 211a and a second injection hole 211b. The first injection hole 211a and the second injection hole 211b may be used as paths through which different materials are injected in a molding process. At least one of the first injection hole 211a or the second injection hole 211b may partially overlap a corresponding one cavity 221 in the vertical direction (Z-direction). For example, at least one of two or more injection holes 211a and 211b constituting the injection hole set 211 may partially overlap the bottom surface 220B of the top mold 220. The first width w1 of each of the plurality of first cavities 221 in the first horizontal direction (Y-direction) may be equal to or greater than the distance d1 between the center of the first injection hole 211a and the center of the second injection hole 211b. Accordingly, a flow of the molding material toward the center of the cavity 221 may be formed as the molding material passes through the injection holes 211a and 211b partially covered by the bottom surface 220B of the top mold 220.

Referring to FIG. 2B, an apparatus 200b for manufacturing a semiconductor package according to an illustrative modified example may have the same or similar features as those described with reference to FIG. 2A, except for the shapes of the plurality of cavities 221. Each of the plurality of cavities 221 may have a top surface 221T facing a corresponding injection hole set 211. In an example variation, the top surface 221T of each of the plurality of cavities 221 may have a concave shape toward the upper surface of the top mold 220. The top surface 221T of the cavity 221 having a curvature may form a flow for stirring the molding materials injected into the cavity 221 or may expand the receiving space of the molding compound in which the molding materials are mixed.

Referring to FIG. 2C, an apparatus 200c for manufacturing a semiconductor package according to an example variation may have the same or similar features as those described with reference to FIGS. 2A and 2B, except for the shapes of the plurality of cavities 221. The plurality of cavities 221 may have an inner side surface 221S defining each side wall. In an example variation, the plurality of cavities 221 may have a shape in which the inner side surface 221S is tapered toward the top. Respective inner side surfaces 221S of the plurality of cavities 221 may have a desired (or alternatively, predetermined) dihedral angle (θ) with respect to the upper surface 210U of the bottom mold 210. The dihedral angle (θ) of the inner side surface 221S of each of the plurality of cavities 221 may be smaller than 90 degrees. The inner side surface 221S of the cavity 221 having the desired (or alternatively, predetermined) dihedral angle (θ) may form a flow for stirring the molding materials injected into the cavity 221 or may expand a receiving space of the molding compound in which the molding materials are mixed. In some variations, the lower width of the cavity 221 may be increased by the inclination of the inner side surface 221S, and the injection holes 211a and 211b may be completely exposed from the bottom surface of the top mold 220. Even in this case, the molding materials may contact the inner side surface 221S of the cavity 221 to form a flow toward the center of the cavity 221.

Referring to FIG. 2D, an apparatus 200d for manufacturing a semiconductor package according to an example modification may have the same or similar features as those described with reference to FIGS. 2A and 2C, except for the arrangement of the injection hole sets 211. The injection hole sets 211 may each include a first injection hole 211a and a second injection hole 211b having a first separation distance sd1 therebetween. The first separation distance sd1 may be determined to overlap the cavity 221 corresponding to both the first injection hole 211a and the second injection hole 211b. The injection hole sets 211 may be arranged with a second separation distance sd2 therebetween. The second separation distance sd2 may be determined to be aligned with the cavities 221 corresponding to the injection hole sets 211 in the vertical direction (Z-direction). For example, the first injection hole set 211A and the second injection hole set 211B may each include the first injection hole 211a and the second injection hole 211b having the first separation distance sd1 therebetween, and may also be separated from each other by a second separation distance sd2 that is smaller or larger than the first separation distance sd1. In some variations, the first separation distance sd1 and the second separation distance sd2 may be substantially the same. In this case, ‘the same’ may be understood as a concept including tolerance and not being intentionally designed differently.

Referring to FIG. 2E, an apparatus 200e for manufacturing a semiconductor package in an illustrative modified example may have the same or similar features as those described with reference to FIGS. 2A and 2D, except for the sizes of the first injection hole 211a and the second injection hole 211b. Each of the injection hole sets 211 may include a first injection hole 211a having a first diameter dm1 and a second injection hole 211b having a second diameter dm2. The first diameter dm1 and the second diameter dm2 may be different from each other. The first diameter dm1 and the second diameter dm2 may be determined according to the type of molding material to be injected, respectively. For example, a second injection hole 211b into which a relatively small amount of a molding material (for example, a curing agent) is injected may have a second diameter dm2 smaller than a first diameter dm1 of a first injection hole 211a into which a main agent is injected.

Referring to FIG. 2F, an apparatus 200f for manufacturing a semiconductor package in an illustrative modified example may have the same or similar features as those described with reference to FIGS. 2A and 2E, except for the number of injection holes of the injection hole sets 211. The injection hole sets 211 may include a first injection hole 211a, a second injection hole 211b, and a third injection hole 211c, respectively. The first injection hole 211a and the third injection hole 211c, which are located at opposite ends in the first horizontal direction (Y-direction), may partially overlap with the corresponding cavity 221. The first injection hole 211a and the third injection hole 211c may be provided as injection paths for different types of molding materials.

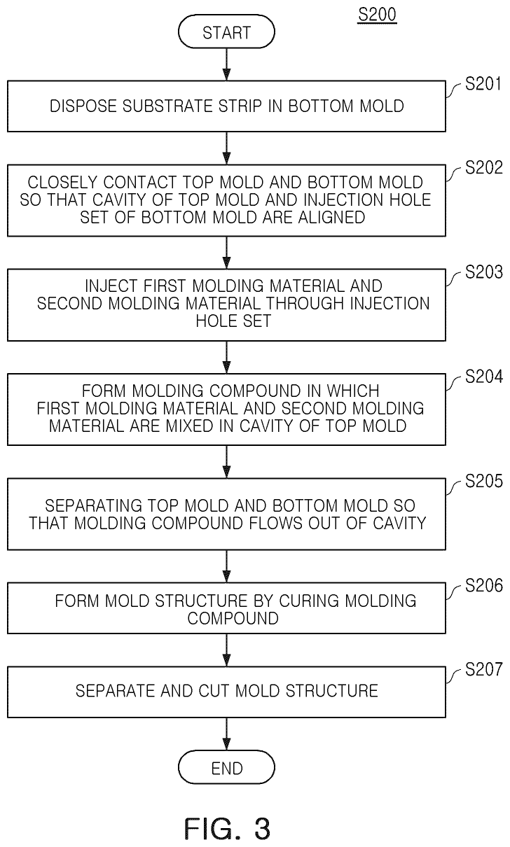

FIG. 3 is a flow chart illustrating a method (S200) for manufacturing a semiconductor package according to an example embodiment.

Referring to FIG. 3, the method (S200) for manufacturing a semiconductor package according to an example embodiment may include an operation of disposing a substrate strip in a bottom mold (S201), an operation of closely contacting a top mold and a bottom mold (e.g., coupling a top mold and a bottom mold to contact each other) (S202), an operation of injecting a first molding material and a second molding material (S203), an operation of forming a molding compound in which the first molding material and the second molding material are mixed in a cavity of the top mold (S204), an operation of separating the top mold and the bottom mold so that the molding compound flows out of the cavity (S205), and an operation of curing the molding compound (S206). According to an example embodiment, an operation (S207) of separating and cutting the mold structure may be further included.

According to an example embodiment, by mixing the first molding material and the second molding material, which are individually injected into the cavity of the top mold, the storage cost of the molding compound and the like may be reduced, and/or the productivity of the semiconductor package may be improved. Hereinafter, with reference to FIGS. 4a to 7, a method of manufacturing a semiconductor package according to an example embodiment (S200) will be described in detail.

FIG. 4 is a drawing illustrating ‘S201’ and ‘S202’ of FIG. 3.

Referring to FIG. 4, a substrate strip 10 in which a plurality of semiconductor chips 20 are disposed in a horizontal direction (X and Y-directions) may be arranged in a bottom mold 210. The bottom mold 210 may include injection hole sets 211 arranged on one side of the substrate strip 10. For example, a pair of substrate strips 10 spaced apart in a second horizontal direction (X-direction) may be disposed on a bottom mold 210, and injection hole sets 211 may be arranged in a first horizontal direction (Y-direction) between the pair of substrate strips 10.

Thereafter, the top mold 220 may be disposed on the bottom mold 210. The top mold 220 may include a plurality of first cavities 221 open toward the injection hole sets 211. The top mold 220 may be pressed against the bottom mold 210 so that the plurality of cavities 221 communicate with the corresponding injection hole sets 211. Each of the plurality of cavities 221 may overlap the injection holes 211a and 211b of a corresponding injection hole set 211 in a vertical direction (Z-direction). The top mold 220 may include second cavities 222 covering the substrate strip 10. A release film such as a Fluorinated Ethylene Propylene (FEP) film, a fluorine-impregnated glass cloth, a Polyethylene Terephthalate (PET) film, an Ethylene Tetra fluoro Ethylene (ETFE) film, a PolyPropylene (PP) film, a Polyvinylidene Chloride (PVDC) film, or the like may be provided on the lower surface of the top mold 220.

The substrate strip 10 may include a plurality of package substrates (e.g., printed circuit boards) that are integrally connected. The semiconductor chips 20 may be electrically connected to the substrate strip 10 in a flip-chip manner or a wire bonding manner. In an example embodiment, the plurality of substrate strips 10 may be disposed on both sides of the injection hole sets 211, which are arranged in one direction.

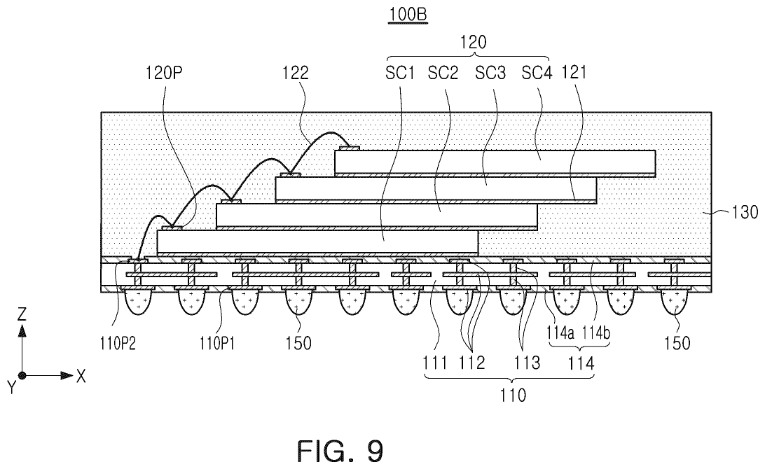

A plurality of semiconductor chips 20 may be disposed vertically and/or horizontally adjacent to each other on the substrate strip 10. The plurality of semiconductor chips 20 may be provided in a greater number than that illustrated in the drawing. The plurality of semiconductor chips 20 may include logic chips such as a central processor (CPU), a graphic processor (GPU), a field programmable gate array (FPGA), an application processor (AP), a digital signal processor, an encryption processor, a microprocessor, a microcontroller, an analog-to-digital converter, an application-specific IC (ASIC), and/or memory chips including volatile memories such as dynamic RAM (DRAM) and static RAM (SRAM), and nonvolatile memories such as phase change RAM (PRAM), magnetic RAM (MRAM), resistive RAM (RRAM), and flash memory. According to an example embodiment, each of the plurality of semiconductor chips 20 may include a plurality of stack chips that are stacked in a vertical direction (Z-direction) (the example embodiment of FIG. 9).

FIGS. 5A and 5B are drawings illustrating ‘S203’ and ‘S204’ of FIG. 3. FIG. 5A illustrates a cross-section along line II-II′ of FIG. 4, and FIG. 5B illustrates a cross-section along line III-III′ of FIG. 4.

Referring to FIGS. 5A and 5B, the first molding material 31 and the second molding material 32 may be injected through the injection hole sets 211, respectively. The first molding material 31 and the second molding material 32 may be injected individually through separate injection holes, for example, the first injection hole 211a and the second injection hole 211b, respectively. The first molding material 31 and the second molding material 32 may be provided into the corresponding cavity 221 by an injection tool (int) such as a pin or a nozzle. Because the first injection hole 211a and the second injection hole 211b are partially covered by the bottom surface 220B of the top mold 220, a flow of the first molding material 31 and the second molding material 32 toward the center of the cavity 221 may be formed. The first molding material 31 and the second molding material 32 may flow to the center of the cavity 221 and be mixed with each other. The bottom mold 210 and the top mold 220 may be configured to heat the first cavity 221 and the second cavity 222. The first cavity 221 and the second cavity 222 may have a temperature atmosphere (e.g., about 150° C. or higher) that may flow the first molding material 31 and the second molding material 32.

The first molding material 31 may include a thermosetting resin such as an epoxy resin and various additives. The epoxy resin may include at least one epoxy component selected from the group consisting of bisphenol-A type epoxy, bisphenol-F type epoxy, rubber modified epoxy, novolac epoxy, cycloaliphatic epoxy, tetra-functional epoxy, acrylic modified epoxy, coal tar modified epoxy, aliphatic chain modified epoxy, cresol novolac epoxy, polyglycol epoxy, cardanol epoxy, brominated epoxy, and phenoxy epoxy. The additive may include a filler, a pigment, a dye, a leveling agent, a release agent, an adhesion promoter, a coupling agent, a softener, and/or the like.

The second molding material 32 may include a curing agent. The curing agent may include at least one of an anhydride curing agent, a cationic curing agent, an imidazole curing agent, a dicyandiamide curing agent, or an amine adduct type.

The acid anhydride curing agent may include at least one selected from the group including dodecenyl succinic anhydride (DDSA), polyadipic acid (PADA), polysebacic acid (PSPA), methyl tetrahydrophthalic anhydride (Me-THPA), methyl hexahydrophthalic anhydride (Me-HHPA), methylhymic anhydride (MHAC), tetrahydrophthalic anhydride (THPA), phthalic anhydride (PA), trimethylicanhydride (TMA), pyromethylic anhydride (PMDA), benzophenon tetracarboxylic anhydride (BTDA), chlorendicanhydride (HET), and tetrabromo phthalic anhydride (TBPA).

The cationic curing agent may include at least one selected from the group consisting of [4-(acetyloxy)phenyl]dimthylsulfonium (OC-6-11-hexafluoroantimonate1-), PC-2508, CXC-1742, CXC-1751, N-benzylpyrazinium hexafluoroantimonate (BPH), XNA-2201, and XNA-2202.

The imidazole curing agent may include at least one selected from the group consisting of 2-methylimidazole, 2-ethyl-4-methylimidazole, 2-undecylimidazole, 2-heptadecylimidazole, 2-phenylimidazole, 2-phenyl-4-methylimidazole, 1-benzyl-2-methylimidazole, 2-ethylimidazole, 2-isopropylimidazole, 2-phenyl-4-benzylimidazole, 1-cyanoethyl-2-methylimidazole, 1-cyanoethyl-2-ethyl-4-methylimidazole, 1-cyanoethyl-2-undecylimidazole, 1-cyanoethyl-2-isopropylimidazole, 1-cyanoethyl-2-phenylimidazole, 1-cyanoethyl-2-methylimidazole-trimellitate, 1-cyanoethyl-2-ethyl-4-methylimidazole-trimellitate, 1-cyanoethyl-2-undecylimidazole-trimellitate, 1-cyanoethyl-2-undecylimidazole-trimellitate, 1-cyanoethyl-2-phenylimidazole-trimellitate, 2,4-diamino-6-2′-methylimidazole-1′))-ethyl-S-triazine, 2,4-diamino-6-2′-ethyl-4-methylimidazoly-1′))-ethyl-S-triazine,2,4-diamino-6-2′-undecylimidazole-1′))-ethyl-S-triazine,2-methylimidazole-isocyanuric acid addition compound,2-phecylimidazole-isocyanuric acid addition compound, 2,4-diamino-6-2′-methylimidazole-1′))-ethyl-S-triazineisocyanuric adduct, 2-phecyl-4,5-dihydroxymethylimidazole, 2-phecyl-4-methyl-5-hydroxymethyl, 2-phecyl-4-benzyl-5-hydroxymethyl imidazole, 4,4′-methylene-bis-2-ethyl-5-methylimidazole) and 1-cyanoethyl-2-phenyl-4,5-di(cyanoethoxymethyl)imidazole.

Thereafter, a molding compound 30 may be formed within the cavity 221. The molding compound 30 may be understood as a material in which a first molding material 31 and a second molding material 32 are mixed. According to an example embodiment, the injection speed, injection amount, or the like of the first molding material 31 and the second molding material 32 may be adjusted to form a molding compound 30 having a desired composition ratio. For example, the molding compound 30 may be an epoxy molding compound, but is not limited thereto. The molding compound 30 may be filled up to the top surface 221T of the cavity 221. The internal space of the cavity 221 may be formed to be larger than that illustrated in the drawing in consideration of the volume of the molding compound 30 desired for a subsequent process (e.g., a volume of the second cavity 222). For example, the top surface 221T of the cavity 221 may be formed higher than that illustrated in the drawing. The top surface 221T of the first cavity 221 and the top surface 222T of the second cavity 222 may be located at different levels (see FIG. 5B).

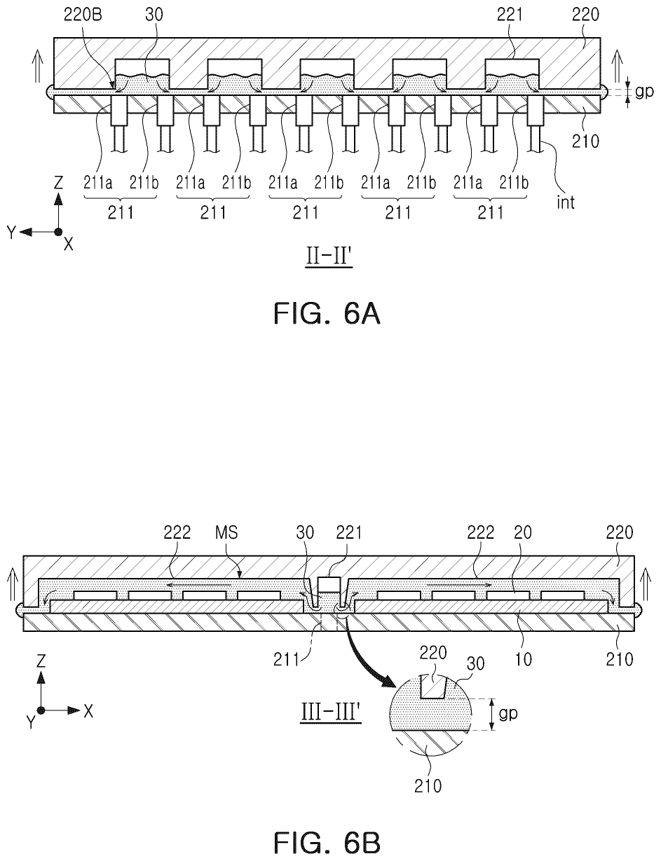

FIGS. 6A and 6B are drawings illustrating ‘S205’ and ‘S206’ of FIG. 3. FIG. 6A illustrates a cross-section along line II-II′ of FIG. 4, and FIG. 6B illustrates a cross-section along line III-III′ of FIG. 4.

Referring to FIGS. 6A and 6B, the top mold 220 and the bottom mold 210 may be spaced apart by a desired (or alternatively, predetermined) interval. The molding compound 30 in the first cavity 221 may flow onto the substrate strip 10 through the gap (gp) between the top mold 220 and the bottom mold 210. The molding compound 30 fills the second cavity 222 and may seal the semiconductor chips 20 on the substrate strip 10. In this case, the gap (gp) between the top mold 220 and the bottom mold 210 may be understood as a separation space between the first cavity 221 and the bottom mold 210. The gap (gp) between the top mold 220 and the bottom mold 210 may be in a range of about 1 mm to about 5 mm. If the gap (gp) is less than about 1 mm, the flow of the molding compound 30 coming out of the first cavity 221 may not be smooth. If the gap (gp) exceeds about 5 mm, the molding compound 30 may overflow, causing defects such as voids. Thereafter, the molding compound 30 may be hardened to form a mold structure MS.

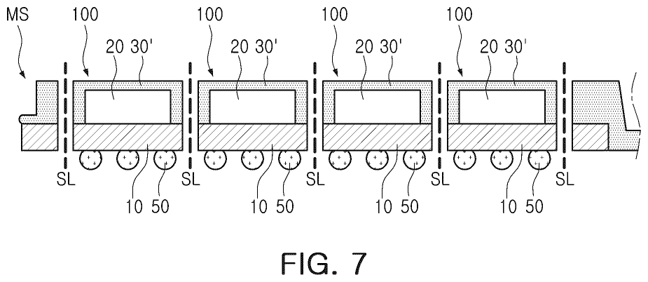

FIG. 7 is a drawing illustrating ‘S207’ of FIG. 3. FIG. 7 illustrates the mold structure MS of FIG. 6B separated from the bottom mold 210 and the top mold 220.

Referring to FIG. 7, the mold structure MS may be cut into a plurality of semiconductor packages 100 along the scribe lane SL. The plurality of semiconductor packages 100 may include a substrate strip 10, a semiconductor chip 20, and an encapsulant layer 30′ separated into package substrate units. The mold structure MS may be cut by a sawing process using a laser drill, a blade, or the like. The encapsulant layer 30′ may be formed by curing the molding compound 30.

According to an example embodiment, before cutting the mold structure MS, a plurality of connecting bumps 50 may be attached to the substrate strip 10. The plurality of connecting bumps 50 may include a low melting point metal (e.g., tin (Sn)) or an alloy thereof (e.g., Sn—Ag—Cu, Sn—Ag, or the like). According to an example embodiment, the plurality of connecting bumps 50 may have a shape in which pillars and balls are combined.

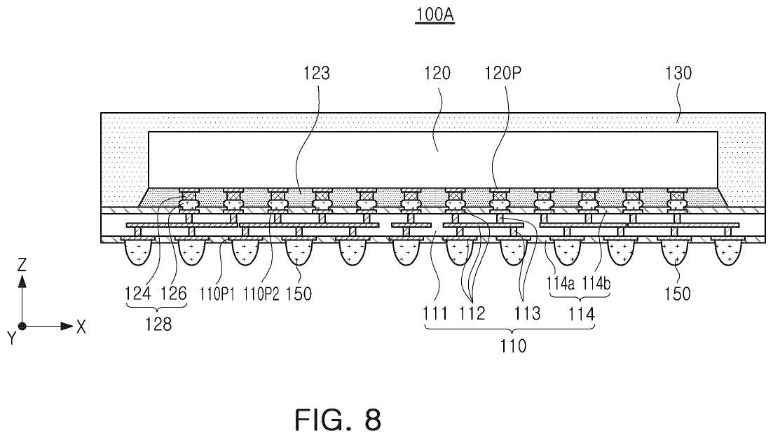

FIGS. 8 and 9 are drawings illustrating semiconductor packages 100A and 100B manufactured according to example embodiments.

Referring to FIG. 8, the semiconductor package 100A of the example embodiment may include a package substrate 110, at least one semiconductor chip 120, an encapsulation layer 130, and connection bumps 150.

The package substrate 110 may be a semiconductor package substrate including a printed circuit board (PCB), a ceramic substrate, a glass substrate, a tape interconnection substrate, or the like. For example, the substrate 110 may be a double-sided PCB or a multi-layer PCB. The package substrate 110 may include an insulating layer 111, interconnection patterns 112, and interconnection vias 113.

The insulating layer 111 may include, for example, a thermosetting resin such as an epoxy resin, a thermoplastic resin such as a polyimide, or a prepreg including an inorganic filler or/and glass fiber (Glass Fiber, Glass Cloth, Glass Fabric), Ajinomoto Build-up Film (ABF), Fire Retardent (FR)-4, or the like. The insulating layer 111 may include a plurality of insulating layers laminated in a vertical direction. For example, the insulating layer 111 may include a core layer and a build-up layer laminated on the upper surface and/or lower surface of the core layer. Depending on the process, the boundary between the plurality of insulating layers may not be clearly distinguished. According to an example embodiment, the insulating layer 111 may include a photosensitive resin such as a Photo Imageable Dielectric (PID).

The interconnection patterns 112 may form electrical connection paths within the insulating layer 111. The interconnection patterns 112 may include an alloy including two or more metals or at least one metal selected from, for example, copper (Cu), aluminum (Al), nickel (Ni), silver (Ag), gold (Au), platinum (Pt), tin (Sn), lead (Pb), titanium (Ti), chromium (Cr), palladium (Pd), indium (In), and zinc (Zn), and/or nonmetal such as carbon (C). Each of the interconnection patterns 112 may be formed of an electrolytically deposited (ED) copper foil, a rolled-annealed (RA) copper foil, ultra-thin copper foils, sputtered copper, copper alloys, or the like. The interconnection patterns 112 may include a plurality of pattern layers spaced apart in the vertical direction. The plurality of pattern layers may extend horizontally at respective vertical levels. The interconnection patterns 112 may include fewer or more pattern layers than those illustrated in the drawing. The interconnection patterns 112 may include lower connection terminals 110P1 and upper connection terminals 110P2. The lower connection terminals 110P1 may be pads of the lowermost interconnection patterns 112, and the upper connection terminals 110P2 may be pads of the uppermost interconnection patterns 112.

The interconnection vias 113 may electrically connect the interconnection patterns 112 within the insulating layer 111. The interconnection vias 113 may include an alloy including two or more metals or at least one metal from among, for example, copper (Cu), aluminum (Al), nickel (Ni), silver (Ag), gold (Au), platinum (Pt), tin (Sn), lead (Pb), titanium (Ti), chromium (Cr), palladium (Pd), indium (In), and zinc (Zn), and/or nonmetal such as carbon (C). The interconnection vias 113 may be formed such that the via holes penetrating at least a portion of the insulating layer 111 are completely filled with a conductive material, or the conductive material is conformally formed along the walls of the via holes. According to an example embodiment, at least some of the interconnection vias 113 may be formed such that the conductive material is coated along the walls of the via holes, and the space inside the via holes surrounded by the conductive material is filled with an insulating material.

The package substrate 110 may further include a protective layer 114. The protective layer 114 may be formed on the upper surface and/or lower surface of the insulating layer 111. For example, the protective layer 114 may include a lower protective layer 114a and an upper protective layer 114b. The lower protective layer 114a may include an opening that exposes at least a portion of the lower connection terminals 110P1. The upper protective layer 114b may include an opening that exposes at least a portion of the upper connection terminals 110P2. The protective layer 114 may be formed using, for example, a solder resist.

At least one semiconductor chip 120 may be disposed such that the connection pads 120P face the package substrate 110. At least one semiconductor chip 120 may be electrically connected to the upper connection terminals 110P2 through conductive bumps 128. The conductive bumps 128 may include a pillar portion 124 and a solder portion 126. The pillar portion 124 may include copper (Cu) or an alloy of copper (Cu), and the solder portion 126 may include a low melting point metal, for example, tin (Sn) or an alloy including tin (Sn—Ag—Cu)). Depending on the example embodiment, the conductive bumps 128 may include only the pillar portion 124 or only the solder portion 126. The conductive bumps 128 may be surrounded by an underfill 123. The underfill 123 may have a capillary underfill (CUF) structure, but may also have a molded underfill (MUF) structure integrated with the second encapsulant layer 132 according to an example embodiment.

At least one semiconductor chip 120 may be a bare semiconductor chip in which a separate bump or interconnection layer is not formed, but example embodiments are not limited thereto, and may be a packaged type semiconductor chip. At least one semiconductor chip 120 may include a semiconductor wafer formed of or including a semiconductor element such as silicon, germanium, or a compound semiconductor such as silicon carbide (SiC), gallium arsenide (GaAs), indium arsenide (InAs), or indium phosphide (InP), and an integrated circuit (IC) formed on the semiconductor wafer.

At least one semiconductor chip 120 may be a logic chip including a central processor (CPU), a graphic processor (GPU), a field programmable gate array (FPGA), an application processor (AP), a digital signal processor, an encryption processor, a microprocessor, a microcontroller, an analog-to-digital converter, an application-specific IC (ASIC), or the like. According to an example embodiment, at least one semiconductor chip 120 may further include a memory chip including a volatile memory such as a dynamic RAM (DRAM), a static RAM (SRAM), or the like, and a nonvolatile memory such as a phase change RAM (PRAM), a magnetic RAM (MRAM), a resistive RAM (RRAM), a flash memory, or the like.

The encapsulant layer 130 may include a thermosetting resin such as an epoxy resin, or a prepreg, an Ajinomoto Build-up Film (ABF), a Fire Retardent (FR)-4, a Bismaeleimide-Triazine (BT), an Epoxy Molding Compound (EMC), or the like. The encapsulant layer 130 may be understood to be formed through the manufacturing process described with reference to FIGS. 3 to 7.

The connection bumps 150 may be disposed on the lower connection terminals 110P1 of the package substrate 110. The semiconductor package 100A may be electrically connected to an external device such as a module substrate or a main board through the connection bumps 150. The connection bumps 150 may include, for example, tin (Sn) or an alloy including tin (Sn) (e.g., Sn—Ag—Cu, Sn—Ag, or the like).

Referring to FIG. 9, the semiconductor package 100B of the present example embodiment may include components substantially the same as or similar to the semiconductor package 100A illustrated in FIG. 8, except that it includes a semiconductor chip 120 (hereinafter referred to as a ‘chip stack’) mounted in a wire-bonding manner. Therefore, corresponding components are referred to by the same or similar reference numerals, and redundant descriptions are omitted below.

The chip stack 120 may be mounted on the package substrate 110. The chip stack 120 may include a plurality of stack chips SC1, SC2, SC3 and SC4. The plurality of stack chips SC1, SC2, SC3 and SC4 may be electrically connected to the package substrate 110 by a wire bonding method. The plurality of stack chips SC1, SC2, SC3 and SC4 may be attached to the package substrate 110 and other vertically adjacent stack chips SC1, SC2, SC3 and SC4 by an adhesive film 121. The adhesive film 121 may include an inorganic adhesive or a polymer adhesive. The polymer adhesive may include, for example, a thermosetting polymer, a thermoplastic polymer, or a hybrid resin mixed therewith. The respective connection pads 120P of the plurality of stack chips SC1, SC2, SC3 and SC4 may be electrically connected to the upper connection terminals 110P2 of the package substrate 110 via bonding wires 122.

The plurality of stack chips SC1, SC2, SC3 and SC4 may be memory chips. The plurality of stack chips SC1, SC2, SC3 and SC4 may include nonvolatile memory semiconductor devices such as flash memory, phase-change random access memory (PRAM), magnetoresistive random access memory (MRAM), ferroelectric random access memory (FeRAM), or resistive random access memory (RRAM), and volatile memory devices such as dynamic random access memory (DRAM) or static random access memory (SRAM). The flash memory may be, for example, V-NAND flash memory. The plurality of stack chips SC1, SC2, SC3, and SC4 may be shifted in at least one direction so that the respective connection pads 120P are exposed upward, but the stacking form of the plurality of stack chips SC1, SC2, SC3 and SC4 is not limited to that illustrated in the drawing. The plurality of stack chips SC1, SC2, SC3 and SC4 may be electrically connected to each other through bonding wires 122.

In some example embodiments, the semiconductor package 100B may further include a control semiconductor chip for the plurality of stack chips SC1, SC2, SC3 and SC4. The control semiconductor chip may include various active and/or passive components such as system LSIs, CIS or MEMS, FETs such as planar FETs or FinFETs, and logic devices such as AND, OR, NOT, or the like. The control semiconductor chip may control access to data stored in the plurality of stack chips SC1, SC2, SC3 and SC4. The control semiconductor chip may control write/read operations of the plurality of stack chips SC1, SC2, SC3 and SC4 according to a control command of an external host. The control semiconductor chip may perform wear leveling, garbage collection, bad block management, and/or error correcting code (ECC). The control semiconductor chip may be spaced apart from a plurality of stack chips SC1, SC2, SC3 and SC4, but example embodiments are not limited thereto.

As set forth above, according to some example embodiments, methods and apparatuses for manufacturing a semiconductor package with improved productivity may be provided by mixing a main agent and a curing agent injected individually within a mold.

While some example embodiments have been illustrated and described above, it will be apparent to those skilled in the art that modifications and variations could be made without departing from the scope of the present inventive concepts as defined by the appended claims.

1. A method of manufacturing a semiconductor package, the method comprising:
disposing a substrate strip having a plurality of semiconductor chips in a bottom mold, the bottom mold including sets of injection holes arranged on one side of the substrate strip;
coupling the bottom mold and a top mold to contact each other, the top mold including a plurality of cavities, the plurality of cavities being open toward corresponding ones of the sets of injection holes, respectively;
individually injecting a first molding material and a second molding material into each of the plurality of cavities through injection holes included in a corresponding one of the sets of injection holes, respectively;
forming a molding compound including the first molding material and the second molding material in the plurality of cavities;
separating the top mold and the bottom mold from each other such that the molding compound flows out of the plurality of cavities;
curing the molding compound covering the plurality of semiconductor chips to form a mold structure; and
cutting the mold structure.

2. The method of claim 1, wherein
each of the sets of injection holes includes a first injection hole into which the first molding material is to be injected, and a second injection hole into which the second molding material is to be injected, and
the first injection hole and the second injection hole are spaced apart in a first horizontal direction.

3. The method of claim 2, wherein
a center of the first injection hole and a center of the second injection hole are spaced apart by a first distance in the first horizontal direction, and
a first width of each of the plurality of cavities in the first horizontal direction is equal to or greater than the first distance.

4. The method of claim 2, wherein a second width of each of the plurality of cavities in a second horizontal direction perpendicular to the first horizontal direction is greater than a diameter of each of the first and second injection holes.

5. The method of claim 2, wherein each of the first injection hole and the second injection hole partially overlaps a corresponding one of the plurality of cavities in a vertical direction.

6. The method of claim 2, wherein a diameter of the first injection hole and a diameter of the second injection hole are different from each other.

7. The method of claim 1, wherein respective top surfaces of the plurality of cavities are concave toward an upper surface of the top mold.

8. The method of claim 1, wherein respective inner side surfaces of the plurality of cavities have a dihedral angle less than 90 degrees with respect to an upper surface of the bottom mold.

9. The method of claim 1, wherein
the first molding material includes a thermosetting resin, and
the second molding material includes a curing agent.

10. The method of claim 9, wherein
the thermosetting resin includes an epoxy resin, and
the curing agent includes at least one of an anhydride curing agent, a cationic curing agent, an imidazole curing agent, a dicyandiamide curing agent, or an amine adduct type.

11. The method of claim 1, wherein an internal temperature of the plurality of cavities into which the first molding material and the second molding material are injected is about 150° C. or higher.

12. The method of claim 1, wherein in the separating the top mold and the bottom mold, a gap between the top mold and the bottom mold is in a range of about 1 mm to about 5 mm.

13. A method of manufacturing a semiconductor package, the method comprising:
disposing a substrate strip in a bottom mold, the bottom mold including a plurality of injection holes;
coupling a top mold and the bottom mold to contact each other, the top mold including a plurality of cavities open toward the plurality of injection holes, each of the plurality of cavities vertically overlapping at least two injection holes adjacent to each other, among the plurality of injection holes;
injecting a first molding material and a second molding material into the at least two injection holes, respectively;
forming a molding compound including the first molding material and the second molding material in the plurality of cavities;
separating the top mold and the bottom mold such that the molding compound flows onto the substrate strip; and
forming a mold structure by curing the molding compound.

14. The method of claim 13, wherein at least one of the at least two injection holes partially overlaps a bottom surface of the top mold in a vertical direction.

15. The method of claim 13, wherein
the first molding material includes a thermosetting resin, and
the second molding material includes a curing agent.

16. The method of claim 13, wherein the molding compound includes an epoxy molding compound.

17. The method of claim 13, wherein in the separating the top mold and the bottom mold, a gap between a bottom surface of the top mold and the bottom mold is about 1 mm or more.

18. (canceled)

19. (canceled)

20. (canceled)
